(19) United States
(12) Patent Application Publication
(10) Pub. No.: US 2025/0007407 A1
(43) Pub. Date: Jan. 2, 2025

(54) Voltage Supply Circuit for an Analog Output

(71) Applicant: IFM Electronic GmbH, Essen (DE)

(72) Inventor: Heinz Walter, Hergatz (DE)

(73) Assignee: IFM Electronic GmbH, Essen (DE)

(21) Appl. No.: 18/752,774

(22) Filed: Jun. 24, 2024

(30) Foreign Application Priority Data
Jun. 28, 2023 (DE) 10 2023 117 016.3

(51) Int. Cl. H02M 3/158; G01R 19/00

(52) U.S. Cl. CPC H02M 3/158; G01R 19/0084

(57) ABSTRACT

A voltage supply circuit for an analog output is disclosed. The circuit comprises a DC/DC converter comprising a supply output, a voltage reference, a DC supply voltage feedback terminal, a first p-channel MOSFET comprising a first gate terminal, a first source terminal and a first drain terminal, and a signal input where the voltage value provided at the first analog output is supplied to the voltage supply circuit and sampled by the first gate terminal. The first source terminal is connected to the supply output via a first resistor and the first drain terminal is connected to the feedback terminal and 0 volts via a second resistor. The value of the DC supply voltage is formed by adding a constant surplus voltage to the sampled voltage value. Further disclosed is a voltage supply circuit comprising two p-channel MOSFETs in series and a measuring device having the voltage supply circuit disclosed.

### CROSS REFERENCE TO RELATED PATENT APPLICATIONS

This application claims priority to German Patent Application 10 2023 117 016.3 filed on Jun. 28, 2023 entitled “Spannungsversorgungsschaltung für einen Analogausgang” (Voltage Supply Circuit for an Analog Output) by Heinz Walter, the entire disclosure of which is incorporated herein by reference in its entirety.

### BACKGROUND OF THE INVENTION

### 1. Field of the Invention

The present invention relates to a voltage supply circuit for an analog output, in particular of a measuring device. Furthermore, the present invention relates to a measuring device comprising a sensor element and at least one such voltage supply circuit.

### 2. Description of Related Art

Electronic devices such as measuring devices with analog outputs are already known from the prior art. At the analog output, a value, in particular a measured value, for example a measured value detected by means of a sensor element, is mapped linearly to an electrotechnical quantity, in particular to a current or a voltage in a specific range of the quantity, such as 4-20 mA for the current. The electrical quantity is then tapped as a signal by a control unit, and processed further, for example, in a process control system.

It is known from the prior art that the electrotechnical quantity is adjusted by use of an operating voltage provided in the measuring device as a function of the measured value. For example, a current signal is adjusted directly by a current regulator from the operating voltage or a voltage signal is adjusted directly by a voltage regulator from the operating voltage. However, there is often an unfavorable relation between the operating voltage, the load applied at the analog output and the electrical quantity to be adjusted in such a way that the quantity can only be adjusted with high power loss. For example, such a relation is present if, with a 36 V operating voltage and a mapping of the measured value to a 4-20 mA current signal, the load is very low. for example almost 0 ohms.

### SUMMARY OF THE INVENTION

Described herein is a circuit for voltage supply by means of which the electrotechnical quantity can be provided at the analog output with low power loss. A voltage supply circuit for an analog output is thus disclosed. The circuit comprises a DC/DC converter comprising a supply output, an internal or external reference voltage reference and a feedback terminal for providing a DC supply voltage at the supply output, a first p-channel MOSFET comprising a first gate terminal, a first source terminal and a first drain terminal, and a first signal input via which the voltage value provided at the first analog output is supplied to the voltage supply circuit and sampled by the first gate terminal, wherein the first source terminal is connected to the supply output via a first resistor and the first drain terminal is connected to the feedback terminal and to 0 volts via a second resistor, and wherein the value of the DC supply voltage is formed by adding a constant surplus voltage to the sampled voltage value. The invention further relates to a corresponding voltage supply circuit comprising two p-channel MOSFETs connected in series with one another and a measuring device comprising one of the aforementioned voltage supply circuits.

### BRIEF DESCRIPTION OF THE DRAWINGS

In the following, the invention is explained in more detail with reference to the attached drawings based on preferred exemplary embodiments. The term figure is abbreviated as Fig. in the drawings.

In the drawings:

FIG. 1 shows a circuit diagram of a voltage supply circuit according to the first aspect of the invention and further elements;

FIG. 2 shows a diagram of the supply voltage and the output voltage provided at the first analog output in a voltage supply circuit according to FIG. 1;

FIG. 3 shows a circuit diagram of a voltage supply circuit according to the second aspect of the invention; and

FIG. 4 shows a diagram of the supply voltage, the output voltage provided at the first analog output and the output voltage provided at the second analog output in a voltage supply circuit according to FIG. 3.

### DESCRIPTION OF THE PREFERRED EMBODIMENTS

Advantages of the claimed aspects of the invention are explained below and preferred modified embodiments of the aspects of the invention are further described below. Explanations, in particular of advantages and definitions of features, are basically descriptive and preferred, but not limiting examples. If an explanation is limiting, this is explicitly mentioned. In particular, the invention is explained with respect to a measuring device, wherein the value mapped to the signal is, for example, a measured value. However, it is explicitly understood that with respect to another device, the value may be a value other than a measured value, for example any value of a control loop.

Insofar as elements are designated with the aid of numbering, for example “first element”, “second element” and “third element”, this numbering is provided purely for differentiation in the designation and does not represent any dependency of the elements on one another or a mandatory sequence of the elements. This means in particular that, for example, a device or a method does not have to comprise a “first element” in order to comprise a “second element”. The device or method can also comprise a “first element” and a “third element” without necessarily comprising a “second element”. Several units of an element of a single numbering may also be provided, for example several “first elements”.

According to one aspect of the invention, a voltage supply circuit for a first analog output, in particular of a measuring device, is provided. The voltage supply circuit comprises a DC/DC converter having a supply output; an internal or external reference voltage reference and a feedback terminal, wherein the DC/DC converter is configured to provide a DC supply voltage at the supply output. Furthermore, the voltage supply circuit comprises: a first p-channel MOSFET with a first gate terminal, a first source terminal and a first drain terminal; and a first signal input, via which the voltage value provided at the first analog output is supplied to the voltage supply circuit and sampled by the first gate terminal. Here, the first source terminal is connected via a first resistor to the supply output and the first drain terminal to the feedback terminal and via a second resistor to 0 volts, also known as ground or GND, and the value of the DC supply voltage is formed by adding a constant surplus voltage to the sampled voltage value.

If the voltage supply circuit is provided for an analog output stage, it is configured to supply the electronic components associated to the analog output stage with the DC supply voltage. This is, for example, a current regulator or a voltage regulator, by means of which the measured value is mapped to a corresponding electrotechnical quantity at the analog output.

A DC/DC converter is an electrical circuit that converts a DC voltage supplied at the input into a DC voltage with a higher, lower or inverted voltage level with high efficiency compared to a linear voltage regulator. Insofar as the DC/DC converter comprises an internal or external reference voltage reference and a feedback terminal, it is configured in such a way that the via the DC supply voltage the voltage provided at the feedback terminal is exactly set equal to that of the internal or external reference voltage reference. In particular, the reference voltage reference and the feedback terminal lead to inputs of an operational amplifier of the DC/DC converter.

A p-channel MOSFET is a metal-oxide semiconductor field-effect transistor (MOSFET) in which positively charged charge carriers (holes, defect electrons) act as majority charge carriers to conduct the electrical current in the channel, i.e. between the source terminal and the drain terminal. The internal resistance of the drain-source path is controlled by the voltage between the gate terminal and the source terminal. The p-channel MOSFET is in particular a p-channel MOSFET of the enhancement type.

Insofar as two terminals or electronic components are connected to each other, this is understood to mean that the terminals or electronic components are electrically conductively connected to each other.

The first aspect of the invention described above includes the technical teaching that the DC supply voltage provided by the DC-DC converter is fed back to the feedback terminal via the first resistor, the first p-channel MOSFET and the second resistor, wherein the output voltage of the first analog output, which is dependent on the signal, is provided at the first gate terminal. In this way, the DC supply voltage is controlled to follow the signal, while always exceeding the output voltage by a constant surplus voltage. The constant surplus voltage arises from the voltage drop across the first resistor, which is formed by the constant current throughout the entire feedback path and is based on the source terminal of the first MOSFET, wherein additionally the substantially constant gate-source voltage of the MOSFET is added to the analog signal voltage. The constant current through the feedback path is determined by the level of the reference voltage and the value of the second resistor at the feedback terminal. The DC supply voltage is set so that exactly this current flows. Advantageously, the constant surplus voltage can then be set at least approximately corresponding to the voltage drop at the regulator for providing the signal, so that the DC supply voltage always corresponds to the DC supply voltage required at the regulator for providing the signal with minimum power loss. In other words, the DC supply voltage equals the amount of the sum of the voltage value at the analog output and the voltage requirement at the regulator which adjusts the signal output at the analog output, and thus enables the signal output at the analog output to be adjusted with the lowest possible power loss.

The first aspect of the invention provides a DC supply voltage for a single analog output. According to a second aspect of the invention, the object is achieved by a voltage supply circuit for two preferably reciprocal analog outputs, in particular of a measuring device, comprising a DC/DC converter with a supply output, an internal or external reference voltage reference and a feedback terminal, wherein the DC/DC converter is configured to provide a DC supply voltage at the supply output. Furthermore, the voltage supply circuit comprises a first p-channel MOSFET with a first gate terminal, a first source terminal and a first drain terminal and a second p-channel MOSFET with a second gate terminal, a second source terminal and a second drain terminal as well as a first signal input, via which the voltage value provided at a first analog output is supplied to the voltage supply circuit and sampled by the first gate terminal, and a second signal input, via which the voltage value provided at a second analog output is supplied to the voltage supply circuit and sampled by the second gate terminal. Here, the first source terminal is connected via a first resistor to the supply output, the first drain terminal is connected to the second source terminal and the second drain terminal is connected to the feedback terminal and via a second resistor to 0 volts, also known as ground or GND, and the value of the DC supply voltage is formed by adding a constant surplus voltage to the higher of the two sampled voltage values.

Insofar as the first analog output and the second analog output are reciprocal to each other, they map the measured value to the same electrotechnical quantity in the same quantity range, wherein, however, the limits of the quantity ranges are interchanged. For example, if the signal is mapped to 4-20 mA current at the first analog output, it is mapped to 20-4 mA with inverse proportionality at the second analog output. The sum of the quantities output at the analog outputs is always the same, in the above example always 24 mA. Two reciprocal analog outputs are provided, for example, for measuring devices that have to meet certain safety requirement levels, for example SIL2, wherein in this case the sum of the quantities output at the analog outputs is used as a control value for the functionality of the measuring device. In principle, however, designs in which the two analog outputs are not reciprocal to each other are also encompassed by the invention. This means that the signals to be output can also be formed completely independently of each other, for example by one output representing pressure and the other representing temperature.

The second aspect of the invention described above comprises essentially the same technical teaching as the first aspect of the invention, wherein the first p-channel MOSFET and the second p-channel MOSFET are connected in series between the first resistor and the second resistor. In this way, the DC supply voltage is always determined by the higher of the two voltages provided at the analog outputs and is thus always sufficient to supply both analog outputs.

The first aspect of the invention has a further advantage if the signal output at the first analog output is mapped to an output voltage. In this case, it is necessary to provide a current limit in order to slow down the output current when the load increases up to a load-side short circuit. Advantageously, the slowing-down of the output-side current can be implemented from the DC supply voltage with low power loss, in particular compared to a significantly higher operating voltage of the measuring device that could otherwise be used to supply the analog output.

The object is achieved according to a further aspect of the invention by a voltage supply circuit according to a first or second aspect of the invention with the modification that instead of a p-channel MOSFET or two p-channel MOSFETs, a pnp Darlington circuit is used, wherein respectively a base of the Darlington circuit corresponds to a gate terminal of a p-channel MOSFET, an emitter of the Darlington circuit corresponds to a source terminal of a p-channel MOSFET and a collector of the Darlington circuit corresponds to a drain terminal of a p-channel MOSFET. Moreover, a pnp transistor with high current gain can be used instead of a p-channel MOSFET or pnp Darlington circuit if a diode or a resistor is connected in series with the base terminal, since otherwise the feedback voltage cannot reach the level of the reference voltage reference at zero volts at the analog output.

The embodiments of the voltage supply circuit described below may relate to any aspect of the invention described above. Insofar as described features relate only to one of the described aspects of the invention, this is explicitly stated or is immediately apparent from the terms used.

In an advantageous embodiment of the respective voltage supply circuit, a DC input voltage is between 18 and 36 V, preferably 24 V. For example, the operating voltage of a measuring device comprising the voltage supply circuit is then used as the DC input voltage and a further voltage source or a further voltage level can be advantageously dispensed with. Furthermore, the reference voltage reference is advantageously 0.9 V.

In a further, preferred embodiment, the first analog output is configured to output a 4-20 mA signal and/or the second analog output is configured to output a 20-4 mA signal. The analog outputs are then associated to a current regulator or respectively to a current regulator, which adjusts or adjust the output signal depending on a measured value, for example. Advantageously, a 4-20 mA signal or a 20-4 mA signal can be supplied by use of the voltage supply circuits of the first aspect and/or the second aspect with particularly low loss, i.e. with particularly low power loss.

In a further preferred embodiment, to which partial reference has already been made in the foregoing, the voltage supply circuit comprises at least one current regulator for adjusting a signal to be output at the first analog output and/or the second analog output, wherein the current regulator is connected to the supply output. Preferably, the voltage supply circuit comprises one current regulator for each analog output, wherein each current regulator is connected to the supply output.

Particularly preferably, the first resistor and the second resistor are configured such that the DC supply voltage corresponds to the sum of the output voltage provided at the first analog output and a constant surplus voltage or the sum of the output voltage provided at the second analog output and the constant surplus voltage. The constant surplus voltage can then advantageously correspond to the voltage requirement of the current regulators and/or further loads in the voltage supply circuit that exceeds the voltage amounts provided at the analog outputs. In this way, the power loss for providing the signal at the analog output or analog outputs can be minimized to a particularly large extent.

In one embodiment, the constant surplus voltage corresponds to a voltage drop at the at least one current regulator or the two current regulators that are provided for each analog output. The reference level of the constant surplus voltage is determined by the output voltage provided at the analog output or analog outputs. As a result, the voltage drop at the current regulator or the current regulators and thus the loads to be supplied are sufficiently taken into account in order to achieve a low power loss when adjusting the signal or signals.

In an alternative embodiment, the constant surplus voltage corresponds to the sum of the voltage drop across the first resistor, a gate-source voltage of the first p-channel MOSFET or a gate-source voltage of the second p-channel MOSFET and the voltage value at the first or second analog output, wherein the first p-channel MOSFET is associated to the first analog output and, correspondingly, the second p-channel MOSFET is associated to the second analog output. The gate-source voltage of the respective p-channel MOSFET is added in the voltage supply circuit to the output voltage provided at the analog output or analog outputs and the voltage drop across the first resistor. If this is also taken into account in the constant surplus voltage, the loads to be supplied are taken into account even more precisely in order to achieve a low power loss when adjusting the signal or signals.

For example, the constant surplus voltage is between 3 and 7 V, in particular 5 V, wherein a low-loss supply of one or two reciprocal analog outputs is usually possible in this voltage range.

In a further embodiment, the voltage supply circuit comprises at least one voltage regulator for converting the DC supply voltage into an additional DC voltage at a load output for a further load.

The voltage regulator is in particular a linear regulator such as a Low-Drop-Out voltage regulator (LDO regulator). A voltage regulator stabilizes an electrical DC voltage as the operating voltage for a circuit in order to compensate for fluctuations in the input voltage over wide ranges. In addition to the analog output or analog outputs, the DC supply voltage can then also be used to provide a further voltage level at DC voltage for further loads, in particular if this voltage level is closer to the lowest voltage level of the DC supply voltage than, for example, the operating voltage of a measuring device, the DC input voltage provided at the DC/DC converter and/or the reference voltage.

According to a third aspect of the invention, the object is achieved by a measuring device comprising a sensor element, a voltage supply circuit according to the first aspect of the invention or according to the second aspect of the invention and at least one regulator for adjusting a signal to be output at the first analog output and/or a signal to be output at the second analog output which is proportional to a measured value detected by means of the sensor element. By use of the measuring device, the advantages described above with regard to the voltage supply circuit can be achieved accordingly.

In a preferred embodiment of the measuring device, the signal at the first analog output is mapped to 4-20 mA and/or at the second analog output to 20-4 mA. One current regulator or a respective current regulator, which regulates/regulate the output signal as a function of the measured value, is/are then associated to the analog outputs. Advantageously, a 4-20 mA signal or a 20-4 mA signal can be supplied with particularly low loss in the measuring device according to the third aspect of the invention.

In yet another preferred embodiment of the measuring device, the voltage supply circuit comprises at least one voltage regulator for converting the DC supply voltage into a constant DC voltage at a load output for a further load. The measuring device then comprises at least one further load connected to the load output. Advantageously, the voltage level of the DC supply voltage can then be used for providing a further voltage level at DC voltage with low loss, in particular a voltage level that is close to the lowest voltage level of the DC supply voltage.

The described exemplary embodiments are merely examples, which can be modified and/or supplemented in a variety of ways within the scope of protection defined by the claims. Each feature described for a particular exemplary embodiment can thus be used independently or in combination with other features in any other exemplary embodiment. Each feature that is described for an exemplary embodiment of a particular claim category can also be used in a corresponding manner in an exemplary embodiment of another claim category.

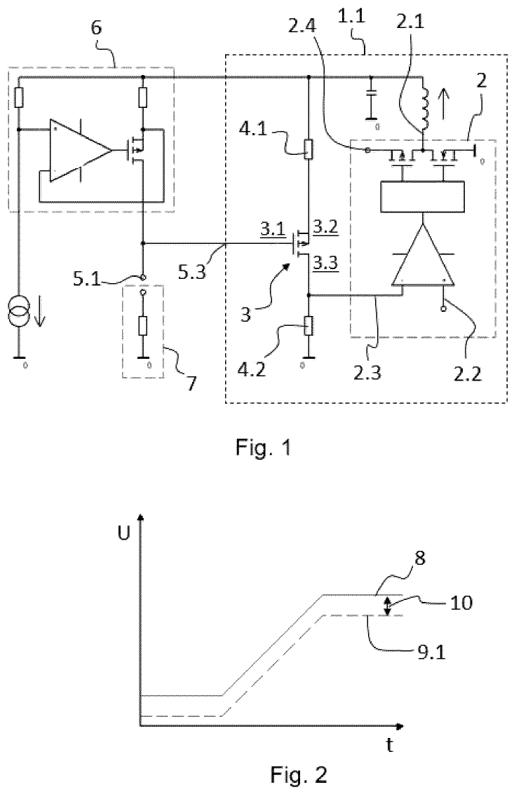

FIG. 1 shows a circuit diagram of a voltage supply circuit 1.1 according to the first aspect of the invention comprising a DC/DC converter 2, a first p-channel MOSFET 3 as well as a first resistor 4.1 and a second resistor 4.2. Here, the DC/DC converter 2 comprises a supply output 2.1, a reference voltage reference 2.2 and a feedback terminal 2.3 and is further connected to a DC input voltage via an input terminal 2.4. The DC input voltage is, for example, an operating voltage of a measuring device and is further, for example, 32 V. At the supply output 2.1, the DC/DC converter 2 outputs a supply voltage following the voltage provided at the first analog connection 5.1, wherein an additive surplus voltage depends on the ratio between the resistors 4.1 and 4.2.

The first p-channel MOSFET 3 comprises a first gate terminal 3.1, a first source terminal 3.2 and a first drain terminal 3.3. The first gate terminal 3.1 is connected to a first analog output 5.1 via the first signal input 5.3, wherein a current signal output at the analog output 5.1 is shown here only symbolically by means of a current mirror 6. Further, a load 7 is provided at the analog output 5.1, which thus causes a voltage drop at the analog output 5.1. The voltage provided at the first gate terminal 3.1 is therefore determined by the output current signal and the load 7 and in turn determines the resistance of the drain-source path of the first p-channel MOSFET 3.

Furthermore, the first source terminal 3.2 is connected to the supply output 2.1 via the first resistor 4.1 and the first drain terminal 3.3 is connected to the feedback terminal and to 0 volts, also referred to as ground or GND, via a second resistor. In this way, the DC supply voltage is ultimately controlled depending on the load 7 and the current strength of the signal shown here by means of the current mirror 6 by a feedback of the DC supply voltage via the p-channel MOSFET 3 to the feedback terminal 2.3. In this way, the DC supply voltage is adjusted to a constant surplus voltage above the output voltage provided at the analog output 5.1.

FIG. 2 shows this regulation of the DC supply voltage 8, wherein the output voltage 9.1 provided at the first analog output 5.1 is also shown. While the voltage is plotted on the y-axis, the time is plotted on the x-axis. A change in the signal over time is shown in detail, for example, as a result of a change in the measured value, which is represented by the signal. If the output voltage 9.1 provided at the first analog output 5.1 increases as a result of the change in the signal, as shown, the voltage at the first gate terminal 3.1 also increases and thus also the voltage at the first source terminal 3.2 as a barrier that the DC supply voltage 8 must overcome in order to be able to generate the current through the resistor 4.1, which should match the voltage at the feedback terminal 3.2 to the voltage at the reference voltage reference 2.2 via the voltage drop at resistor 4.2 and thus ultimately causes the DC supply voltage 8 to be set correspondingly higher. In this way, the DC supply voltage 8 is spaced at all times by a constant surplus voltage 10 from the output voltage 9.1 provided at the analog output 5.1.

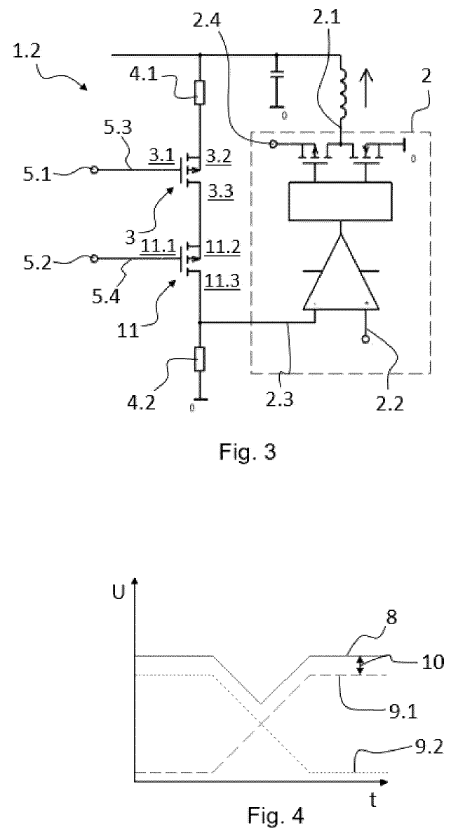

FIG. 3 shows a circuit diagram of a voltage supply circuit 1.2 according to the second aspect of the invention, which corresponds in essential parts to the voltage supply circuit 1.1. A repeated explanation is dispensed with. In contrast to the voltage supply circuit 1.1, the voltage supply circuit 1.2 comprises a second p-channel MOSFET 11 which is connected in series with the first p-channel MOSFET 3 between the first drain terminal 3.3 and the feedback terminal 2.3 or the second resistor 4.2. The second p-channel MOSFET 11 comprises a second gate terminal 11.1, a second source terminal 11.2 and a second drain terminal 11.3. While the second source terminal 11.2 of the described intermediate connection of the second p-channel MOSFET is connected accordingly to the first drain terminal 3.3 and the second drain terminal 11.3 is connected to the second resistor 4.2 and the feedback terminal 2.3, the second gate terminal 11.1 is connected to a second analog output 5.2 via a second signal input 5.4. The first analog output 5.1 and the second analog output 5.2 are preferably connected to each other in such a way that reciprocal signals of the same electrotechnical quantity are output at them.

FIG. 4 shows the regulation of the DC supply voltage 8 in the voltage supply circuit 1.2. As in FIG. 2, the voltage is plotted on the y-axis, while the time is plotted on the x-axis. The output voltage 9.1 provided at the first analog output 5.1 and the output voltage 9.2 provided at the second analog output 5.2 are opposite to each other. Over time, the output voltage 9.1 provided at the first analog output 5.1 increases, while the output voltage 9.2 provided at the second analog output 5.2 simultaneously decreases by the same amount. In this case, the DC supply voltage 8 is determined by the higher one of the two voltages 9.1, 9.2 in such a way that it is spaced apart from the higher one of the two voltages 9.1, 9.2 by a constant surplus voltage 10 at all times.

### LIST OF REFERENCE SYMBOLS

1.1 voltage supply circuit
1.2 voltage supply circuit
2 DC/DC converter
2.1 supply output of DC/DC converter
2.2 reference voltage reference of DC/DC converter
2.3 feedback terminal of DC/DC converter
2.4 input terminal of DC/DC converter
3 first p-channel MOSFET
3.1 gate terminal of first p-channel MOSFET
3.2 source terminal of first p-channel MOSFET
3.3 drain terminal of first p-channel MOSFET
4.1 first resistor
4.2 second resistor
5.1 first analog output
5.2 second analog output
5.3 first signal input
5.4 second signal input
6 current mirror
7 load resistor
8 DC supply voltage
9.1 voltage provided at the first analog output
9.2 voltage provided at the second analog output
10 constant surplus voltage
11 second p-channel MOSFET
11.1 gate terminal of the second p-channel MOSFET
11.2 source terminal of the second p-channel MOSFET
11.3 drain terminal of the second p-channel MOSFET

What is claimed is:

1. A voltage supply circuit (1.1) for a first analog output (5.1), in particular of a measuring device, the voltage supply circuit comprising:
a DC/DC converter (2) comprising a supply output (2.1), an internal or external reference voltage reference (2.2) and a feedback terminal (2.3), wherein the DC/DC converter (2) is configured to provide a DC supply voltage (8) at the supply output (2.1);
a first p-channel MOSFET (3) comprising a first gate terminal (3.1), a first source terminal (3.2) and a first drain terminal (3.3); and
a first signal input (5.3), via which the voltage value (9.1) provided at the first analog output (5.1) is supplied to the voltage supply circuit (1.1) and sampled by the first gate terminal (3.1),
wherein the first source terminal (3.2) is connected to the supply output (2.1) via a first resistor (4.1) and the first drain terminal (3.3) is connected to the feedback terminal (2.3) and to 0 volts via a second resistor (4.2), and
wherein the value of the DC supply voltage (8) is formed by adding a constant surplus voltage (10) to the sampled voltage value (9.1).

2. A voltage supply circuit (1.2) for two preferably reciprocal analog outputs (5.1, 5.2), in particular of a measuring device, the voltage supply circuit comprising:
a DC/DC converter (2) comprising a supply output (2.1), an internal or external reference voltage reference (2.2) and a feedback terminal (2.3), wherein the DC/DC converter (2) is configured to provide a DC supply voltage (8) at the supply output (2.1);
a first p-channel MOSFET (3) comprising a first gate terminal (3.1), a first source terminal (3.2) and a first drain terminal (3.3);
a second p-channel MOSFET (11) comprising a second gate terminal (11.1), a second source terminal (11.2) and a second drain terminal (11.3);
a first signal input (5.3) via which the voltage value (9.1) provided at a first analog output (5.1) is supplied to the voltage supply circuit (1.1) and sampled by the first gate terminal (3.1); and
a second signal input (5.4), via which the voltage value (9.2) provided at a second analog output (5.2) is supplied to the voltage supply circuit (1.1) and sampled by the second gate terminal (11.1),
wherein the first source terminal (3.2) is connected to the supply output (2.1) via a first resistor (4.1), the first drain terminal (3.3) is connected to the second source terminal (11.2) and the second drain terminal (11.3) is connected to the feedback terminal (2.3) and to 0 volts via a second resistor (4.2), and
wherein the value of the DC supply voltage (8) is formed by adding a constant surplus voltage (10) to the respective higher of the two sampled voltage values (9.1, 9.2).

3. The voltage supply circuit according to claim 1, wherein the first analog output (5.1) is configured to output a 4-20 mA signal and/or the second analog output (5.2) is configured to output a 20-4 mA signal.

4. The voltage supply circuit according to claim 1, comprising at least one current regulator for adjusting a signal to be output at the first analog output (5.1) and/or the second analog output (5.2), wherein the current regulator is connected to the supply output (2.1).

5. The voltage supply circuit according to claim 1, wherein the first resistor (4.1) and the second resistor (4.2) are configured such that the DC supply voltage (8) corresponds to the sum of the voltage (9.1) provided at the first analog output (5.1) and a constant surplus voltage (10) or to the sum of the voltage (9.2) provided at the second analog output (5.2) and the constant surplus voltage (10).

6. The voltage supply circuit according to claim 5, wherein the constant surplus voltage (10) corresponds to a voltage drop at the at least one current regulator.

7. The voltage supply circuit according to claim 5, wherein the constant surplus voltage (10) corresponds to the sum of the voltage drop across the first resistor (4.1), a gate-source voltage of the first p-channel MOSFET (3) or a gate-source voltage of the second p-channel MOSFET (11) and the voltage value at the first or the second analog output (5.1, 5.2).

8. The voltage supply circuit according to claim 5, wherein the constant surplus voltage (10) is between 3 and 7 V, in particular 5 V.

9. The voltage supply circuit according to claim 1, comprising at least one voltage regulator for converting the DC supply voltage (8) into an additional DC voltage at a load output for a further load.

10. A measuring device, comprising:
a sensor element;
a voltage supply circuit according to claim 1; and
at least one regulator for adjusting a signal to be output at the first analog output (5.1) and/or a signal to be output at the second analog output (5.2) which is proportional to a measured value detected by means of the sensor element.

11. The measuring device according to claim 10, wherein the signal at the first analog output (5.1) is mapped to 4-20 mA and/or at the second analog output (5.2) to 20-4 mA.

12. The measuring device according to claim 10,
wherein the voltage supply circuit (1.1, 1.2) comprises at least one voltage regulator for converting the DC supply voltage (8) into an additional DC voltage at a load output for a further load; and
comprising at least one further load connected to the load output.
